(19) United States
(12) Patent Application Publication
(10) Pub. No.: US 2008/0094096 A1
(43) Pub. Date: Apr. 24, 2008

(54) Semiconductor testing equipment and semiconductor testing method

(75) Inventors: Satoshi Kishimoto, Osaka (JP); Tomohiko Kanemitsu, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/878,466

(22) Filed: Jul. 24, 2007

(30) Foreign Application Priority Data
Oct. 20, 2006 (JP) 2006-285603
Apr. 27, 2007 (JP) 2007-117817

(51) Int. Cl. G01R 31/26

(52) U.S. Cl. 324/765

(57) ABSTRACT

In testing a large number of semiconductor devices, semiconductor testing equipment of the present invention is provided with combination determining unit 105 that determines the combination of semiconductor devices to be simultaneously tested among semiconductor devices to be tested, on the basis of one of determination results or measured values in separate testing or manufacturing implemented before and stored in a memory 99, and past determination results or measured values stored in the memory 99 in the present testing.

### FIELD OF THE INVENTION

The present invention relates to semiconductor testing equipment and a semiconductor testing method for simultaneously testing the electrical properties of a plurality of semiconductor devices.

### BACKGROUND OF THE INVENTION

Heretofore, in electrically testing a semiconductor device, for example, formed on a wafer substrate, as one of techniques for suppressing the testing costs thereof, a method for simultaneously testing a plurality of semiconductor devices has been widely used.

In this case, a power-source unit and an input-output signal unit of semiconductor testing equipment are connected to the power-source terminal and the input-output terminal of each semiconductor device, respectively, and power and signals are supplied to each semiconductor device in the same timing, to realize simultaneous testing.

When the number of semiconductor devices to be simultaneously tested is larger than the numbers of the power-source units and input-output signal units, one of a current and a voltage is collectively supplied to a plurality of semiconductor devices from one of a power-source unit and an input-output signal unit, to realize simultaneous testing.

However, depending on testing conditions for simultaneously testing a plurality of semiconductor devices as described above, various noises may be generated for reasons, such as the variation of power current of a semiconductor device, interference between output signals, and interference to other semiconductor devices due to the abnormality of electrical properties of a defective semiconductor device.

This may cause instability in desired power source and current supply to or measurement of semiconductor devices that would be determined to be non-defective if they were tested piece by piece. As a result, a non-defective product may be determined as defective, and the yield may be lowered.

Means to solve such problems (for example, refer to Japanese Patent Laid-Open No. 10-125747 (Patent Document 1), Japanese Patent Laid-Open No. 3-163364 (Patent Document 2), and Japanese Patent No. 3834050 (Patent Document 3)) includes a method for continuing the test of semiconductor devices under stable conditions when electrical properties of a plurality of semiconductor devices are simultaneously measured for the above-described test, and if defects are detected in the plurality of semiconductor devices, by interrupting one of power source and input-output signals to semiconductor devices determined as defective by control signals (relay control signals and enable signals) from the semiconductor testing equipment, and removing effects to test results by devices determined as defective.

According to the above-described conventional techniques, however, since the control signals from the semiconductor testing equipment are signals determined from one of determination results and measured values of the test after all the semiconductor devices have been initially tested, optimal number of simultaneous measurements corresponding to the properties of the device and the performance of the semiconductor testing equipment cannot be determined on the basis of the control signals. In addition, although semiconductor devices determined to be defective among the initially tested semiconductor devices are not to be tested, there is possibility that semiconductor devices determined as defective due to the effect of other semiconductor devices are mixed.

Therefore, tests might be performed even though various noises, which are generated when a large number of semiconductor devices are simultaneously measured as described above, cannot be fed back into test conditions. Individual semiconductor devices then could not be accurately tested and there has been possibility to lower the product yield.

Furthermore, control signals from conventional semiconductor testing equipment described in Patent Documents 1 and 2 are signals of simply High and Low, and complicated control signals, such as signals to control the operation of a semiconductor device cannot be outputted. Therefore, when the electrical properties of a large number of semiconductor devices were simultaneously tested, a large number of external circuits, such as relays and gates for physically switching the supply (on/off) of the power and input-output signals to the semiconductor devices to be tested had to be added to the testing tools fixed to the semiconductor testing equipment, leading to rise in costs of the testing tools for simultaneously testing a large number of semiconductor devices.

According to conventional techniques, since the external circuits and semiconductor testing circuits added to the testing tools are connected to the power-source line and the input-output signal line of semiconductor devices as described above, the elevation of impedance of the power-source line and mismatching of characteristic impedance of the input-output signal line are caused, and there is possibility that the external circuit portions and the semiconductor testing circuit in semiconductor devices act as another noise source. Particularly in the test of semiconductor devices on a wafer, for example, when at least 100 semiconductor devices were simultaneously tested, individual semiconductor devices could not be accurately tested because of the effect of the above-described noise between semiconductor devices, and the possibility of lowering product yields was elevated.

### DISCLOSURE OF THE INVENTION

To solve the above-described problems in conventional techniques, it is an object of the present invention to provide semiconductor testing equipment and a semiconductor testing method that can accurately test individual semiconductor devices to surely suppress the lowering of product yields, even when the electrical properties of a large number of semiconductor devices are simultaneously tested, and can surely suppress the elevation of costs of testing tools fixed to the semiconductor testing equipment caused by simultaneous testing.

To solve the above-described problems, semiconductor testing equipment according to the present invention for simultaneously testing electric properties of a plurality of semiconductor devices is equipped with combination determining unit for determining a combination of simultaneous testing for the semiconductor devices to be tested by the semiconductor testing equipment, on the basis of one of determination results or measured values in testing or manufacturing in a separate process implemented before the test conducted using the semiconductor testing equipment (hereafter, also referred to as “test results of the previous process”), and past determination results or measured values in the same test processes using the semiconductor testing equipment (hereafter, also referred to as “past test results in the same test processes”).

In the semiconductor testing equipment, when electrical properties of a plurality of semiconductor devices are simultaneously tested, on the basis of the test results in the previous process and the same test processes, the combination of semiconductor devices to be simultaneously tested is determined using combination determining unit determined according to a control algorithm previously programmed by software and the like, and semiconductor devices to be tested can be tested under stable testing conditions.

Semiconductor testing equipment according to the present invention for simultaneously testing electric properties of a plurality of semiconductor devices is also equipped with combination determining unit for determining a combination of simultaneous testing for the semiconductor devices to be tested in the second test and later, on the basis of one of the test results and measured values in the first testing for the plurality of semiconductor devices, and the performance of the semiconductor testing equipment.

In the semiconductor testing equipment, when a semiconductor device to be tested for the second time and later is retested because the semiconductor device was determined to be defective in the first test, the combination of semiconductor devices to be simultaneously tested can be determined using combination determining unit determined in accordance with control algorithm previously programmed by software and the like on the basis of the determination results or measured value of the test of semiconductor devices and the performance of semiconductor testing equipment, and the semiconductor device to be tested for the second time and later can be retested under more stable testing conditions.

The semiconductor testing equipment of the present invention for simultaneously testing electric properties of a plurality of semiconductor devices is also equipped with device controlling unit wherein device controlling signals for controlling the state of the operation of semiconductor devices not to be tested are programmably generated and supplied in testing, on the basis of one of the determination results and measured values in the first testing for the plurality of semiconductor devices, and one of the combination of simultaneous testing for the semiconductor devices and the performance of the semiconductor testing equipment.

In the semiconductor testing equipment, when a semiconductor device to be tested for the second time and later is retested because the semiconductor device was determined to be defective in the first test, semiconductor devices determined to be non-defective are accessed and the operation of the devices are placed, for example, in a resting state using device controlling unit determined in accordance with control algorithm previously programmed by software and the like. Then, when a semiconductor device determined to be defective is retested by supplying power and input-output signals again from the power-source unit and the input-output signal unit to the semiconductor device determined to be defective for retesting, by controlling the operation of devices determined to be non-defective, the semiconductor device to be tested for the second time and later can be retested under more stable testing conditions.

The semiconductor testing equipment of the present invention is also equipped with resource switching unit for intensively assigning to semiconductor devices to be tested, resources including the power-source unit, the input-output signal unit, and a measuring unit used for testing the semiconductor devices, on the basis of one of the determination results and measured values in the test, and one of the combination and the performance.

In the semiconductor testing equipment, when a semiconductor device to be tested for the second time and later is retested because the semiconductor device was determined to be defective in the first test, by using resource switching unit determined according to a control algorithm previously programmed by software and the like to supply power and input-output signals again from the power-source unit and the input-output signal unit to the semiconductor device determined to be defective, for example, after a plurality of serially connected power-source units have been connected in parallel for retesting, the resource of the semiconductor testing equipment can be intensely assigned to enhance the supply capacity of, for example, power current, and the semiconductor devices determined to be defective can be retested under more stable testing conditions.

The semiconductor testing method of the present invention is a semiconductor testing method including a process for measuring the electrical properties of arbitrarily selected semiconductor devices among the plurality of semiconductor devices; a process for estimating property fluctuation on the basis of the property values and determining semiconductor devices to be simultaneously tested; a process for outputting signals to control the state of the operation of semiconductor devices not to be tested as the device controlling signals; and a process for simultaneously testing semiconductor devices to be tested.

In this method, the electrical properties of arbitrarily selected semiconductor devices among the plurality of semiconductor devices are measured; property fluctuation is estimated on the basis of the property values and the number and combination of semiconductor devices to be simultaneously tested are determined; semiconductor devices not to be tested are set to any mode to bring them in a resting state; and the semiconductor devices to be tested are tested. The processes of estimating the property fluctuation, selecting the number and combination of the semiconductor devices to be simultaneously tested, and separately testing them make it possible to test the semiconductor devices under more stable testing conditions.

According to the present invention, as described above, when the electrical properties of a large number of semiconductor devices are simultaneously tested, the semiconductor devices can be tested under stable testing conditions without being affected by the variation of the power current for semiconductor devices due to the simultaneous testing thereof and various noises, such as the interference between signals.

As a result, even when the electrical properties of a large number of semiconductor devices are simultaneously tested, individual semiconductor devices can be accurately tested, and the lowering of the product yield can be surely suppressed.

Furthermore, when the electrical properties of a large number of semiconductor devices are simultaneously tested, individual semiconductor devices can be tested without adding a large number of external circuits to the testing tools fixed to the testing equipment for physically switching the supply of power and input-output signals to each semiconductor device for simultaneous testing.

As a result, even when the electrical properties of a large number of semiconductor devices are simultaneously tested, the elevation of costs conventionally arising in simultaneous tests for testing tools and the like fixed in testing equipment can be surely suppressed.

### BRIEF DESCRIPTION OF THE DRAWINGS

FIG. 1 is a block diagram showing a configuration of semiconductor testing equipment according to a first embodiment of the present invention;

FIG. 2 is a flow diagram showing the flow of a semiconductor testing method for the semiconductor testing equipment according to the first embodiment;

FIG. 3 is a flow diagram showing the flow of another semiconductor testing method for the semiconductor testing equipment according to the first embodiment;

FIG. 4 is a block diagram showing a configuration of semiconductor testing equipment according to a second embodiment of the present invention;

FIG. 5 is a block diagram showing another configuration of semiconductor testing equipment according to the second embodiment;

FIG. 6 is a block diagram showing further another configuration of semiconductor testing equipment according to the second embodiment;

FIG. 7 is a flow diagram showing the flow of a semiconductor testing method for the semiconductor testing equipment according to the second embodiment;

FIG. 8 is a block diagram showing a configuration of semiconductor testing equipment according to a third embodiment of the present invention;

FIG. 9 is a flow diagram showing the flow of a semiconductor testing method for the semiconductor testing equipment according to the third embodiment; and

FIG. 10 is a flow diagram showing the flow of a semiconductor testing method for the semiconductor testing equipment according to a fourth embodiment of the present invention.

### DESCRIPTION OF THE EMBODIMENTS

Semiconductor testing equipment and semiconductor testing method according to the embodiment of the present invention will be described in detail below referring to the drawings.

### First Embodiment

Semiconductor testing equipment and semiconductor testing method according to the first embodiment of the present invention will be described.

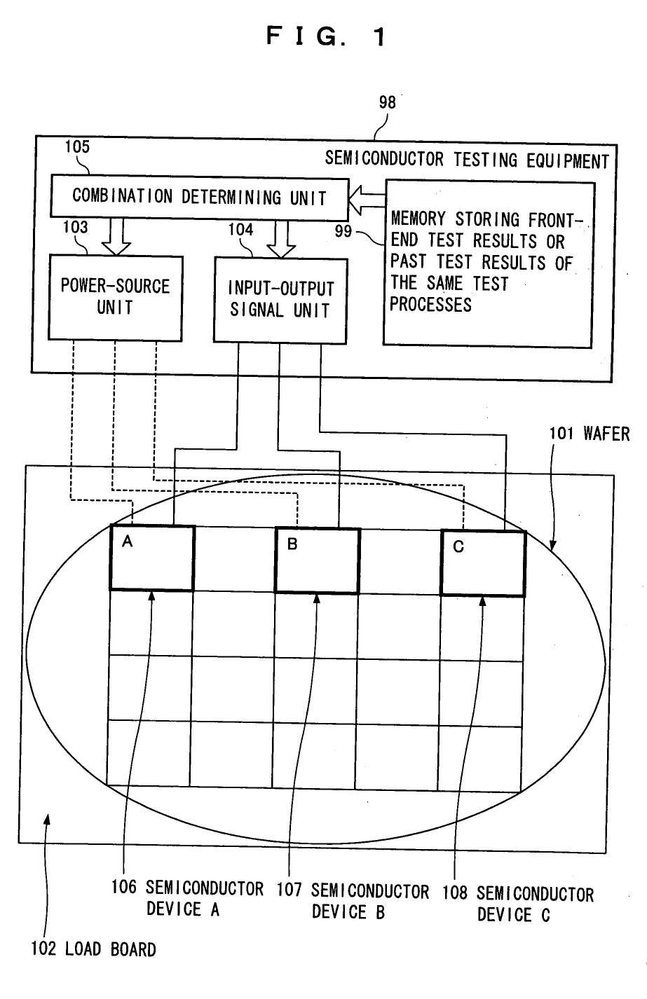

FIG. 1 is a block diagram showing a configuration of semiconductor testing equipment according to the first embodiment, and shows the configuration of simultaneous testing of semiconductor devices using the semiconductor testing equipment 98. The test is constituted of the semiconductor testing equipment 98, a wafer 101, and a load board 102 to become the interface for connection between the semiconductor testing equipment 98 and semiconductor devices on the wafer 101. In place of the semiconductor devices on the wafer 101, a semiconductor device assembly sealed in a package may also be used.

The semiconductor testing equipment 98 is equipped with a power-source unit 103 for supplying voltage and current to the power terminals and input-output terminals of semiconductor devices, and input-output signal unit 104. The power-source unit 103 and the input-output signal unit 104 have a plurality of independent power-source circuits, input-output signal circuits, and ports, to supply voltage and current to each of a plurality of semiconductor devices.

When the number of the power-source units 103 and the input-output signal units 104 is smaller than the number of semiconductor devices to be simultaneously tested, the configuration wherein a power-source unit 103 and an input-output signal unit 104 are collectively connected to an arbitrarily determined number of the power terminals and input-output terminals of semiconductor devices, to supply voltage and current may also be used.

In FIG. 1, although the power-source unit 103 and the input-output signal unit 104 are connected only to a semiconductor device A 106, a semiconductor device B 107, and a semiconductor device C 108 among all semiconductor devices mounted on the wafer 101, for the convenience of explanation, actually, they are connected to a number of simultaneously tested semiconductor devices.

The semiconductor testing equipment 98 is further equipped with a memory 99 that stores previous process test results or past test results of the same test processes, and combination determining unit 105, which are features of the present invention. The memory 99 is a memory that stores one of determination results or measured values in a separate testing process or fabricating process carried out before the testing process using the semiconductor testing equipment 98, and the determination results or measured values of the past test in the same test processes using the semiconductor testing equipment of the present invention. The memory 99 may be a memory assigned in the region of a part of the memory provided in the semiconductor testing equipment 98.

The combination determining unit 105 has a function to determine the combination of semiconductor devices to be simultaneously tested among semiconductor devices to be tested using information stored in the memory 99, composed of one of determination results or measured values in a separate testing process or fabricating process carried out before the testing process using the semiconductor testing equipment of the present invention, and the determination results or measured values of the past test in the testing process using the semiconductor testing equipment of the present invention as input information.

The combination determining unit 105 is one of software and hardware wherein previously programmed control algorithm is incorporated. For example, there is a case wherein signal noise caused by output signals of semiconductor devices, or current consumption or voltage variation of the power source of a semiconductor device affects another semiconductor device as a noise via one of the wafer 101 and the load board 102.

Against such a phenomenon, the combination determining unit 105 determines the number and combination of semiconductor devices to be simultaneously tested in testing on the basis of measured values observed in various testing items, such as the test to measure minute noise, the test vulnerable to the fluctuation of power voltages, and the test that consumes much power current, among the test results of a semiconductor device same as the semiconductor device to be tested in the previous process stored in the memory 99, and/or the test result of a semiconductor device of equivalent circuit configuration to the semiconductor device to be tested measured in the same test processes in the past.

For example, there is a method wherein the number of semiconductor devices simultaneously tested is determined using the threshold voltage of the gate of a transistor (hereafter referred to as the “VT value”), which is one of process parameters in the fabricating process before the testing process. In the semiconductor fabricating process, the characteristic values of a plurality of parameters of the wafer 101 are measured for evaluating the execution of the process. The VT value of a transistor is extracted from the parameters. The VT value is stored in the memory 99 of the semiconductor testing equipment 98 of the present invention. The combination determining unit 105 determines the number of semiconductor devices to be simultaneously tested on the basis of the serial number of the wafer to be tested and the VT value at that time.

Thereby, when a semiconductor testing is conducted, test of the combination of three semiconductor devices, a semiconductor device A 106, a semiconductor device B 107, and a semiconductor device C 108, of all the semiconductor devices on the wafer 101, is determined, and the testing of semiconductor devices to be tested is conducted.

By previously incorporating such an algorithm in the combination determining unit 105, the combination of semiconductor devices to be simultaneously tested among semiconductor devices to be tested can be determined. When a plurality of semiconductor devices selected using the combination determining unit 105 are tested, only the power-source units 103 and input-output signal units 104 connected to the semiconductor devices to be simultaneously tested are operated, and the power-source units 103 and input-output signal units 104 connected to the semiconductor devices not to be tested are not operated.

Next, a semiconductor testing method using semiconductor testing equipment 98 will be described.

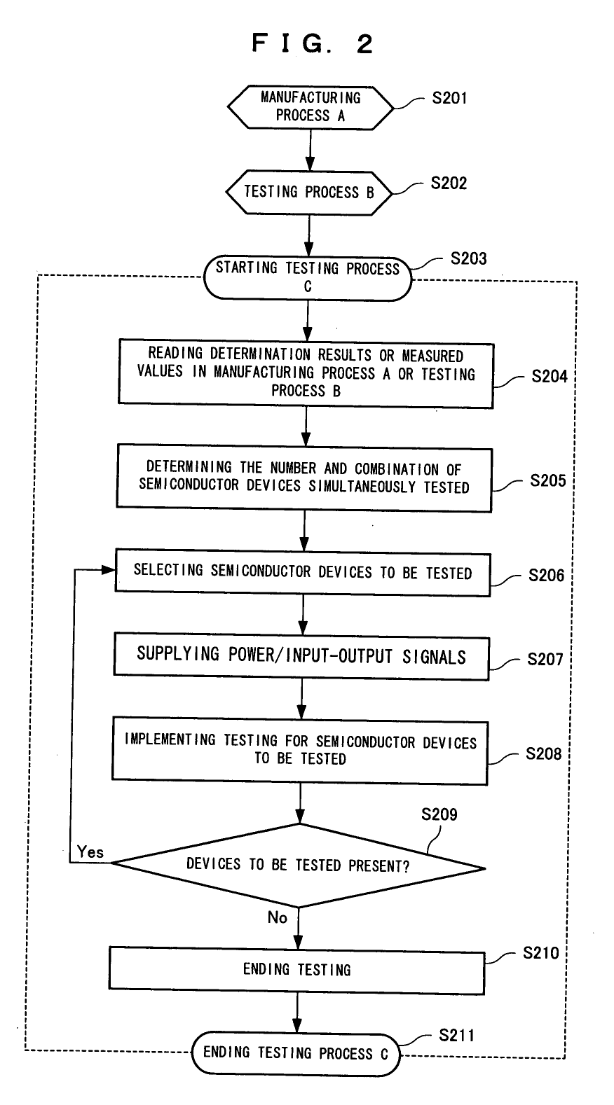

FIG. 2 is a flow diagram showing the flow of a semiconductor testing method for the semiconductor testing equipment 98 according to the first embodiment. In description for the first embodiment, the semiconductor device A 106, the semiconductor device B 107, and the semiconductor device C 108 in the semiconductor testing equipment 98 shown in FIG. 1 are used as examples.

First, the determination results or measured values of testing the properties of the process in the fabricating process A, which is the previous process of the testing process for testing the wafer 101 using the semiconductor testing equipment 98, are extracted (Step S201). For example, in Step S201, the determination results or measured values of the VT value of the transistor, which is one of process parameters showing the execution of the process for the fabricated wafer are extracted.

When there is another testing process B in the previous process of the testing process for testing the wafer 101 using the semiconductor testing equipment 98, the determination results or measured values of the test in the testing process B are extracted (Step S202). For example, in Step S202, the determination results or measured values of the test for the power current of each semiconductor device to the wafer 101 are extracted.

For Step S201 and Step S202, the test results of either one or both may be extracted.

Next, in the testing process C, wafer testing using the semiconductor testing equipment 98 is started (Step S203).

First, among the determination results or measured values of the test in either one of or both Step S201 and Step S202, the determination results or measured values of necessary and sufficient tests for determining the number of semiconductor devices simultaneously tested in the testing process C are loaded in the memory 99 equipped in the semiconductor testing equipment 98 (Step S204).

Then, on the basis of the determination results or measured values of the test in one of the manufacturing process A and the testing process B stored in the memory 99, the combination determining unit 105 determines the combination of simultaneously tested semiconductor devices from the wafer 101. For example, the VT value of a transistor measured in Step S201 and the power current value of each semiconductor device measured in Step S202 are compared with the previously established standard values of each test result, and in the testing item C (Step S203), the number of semiconductor devices to be simultaneously tested is determined (Step S205).

Then, a semiconductor device A 106, a semiconductor device B 107, and a semiconductor device C 108, which are semiconductor devices to be tested, are selected (Step S206), and voltage and current are supplied from the power-source unit 103 and the input-output signal unit 104 of the semiconductor testing equipment 98 to each power-source terminal and each input terminal of these semiconductor devices in the same timing (Step S207).

Then, these semiconductor devices are operated, and simultaneously tested (Step S208). After testing, the presence of semiconductor devices not yet tested is checked (Step S209), and testing is repeated for all the semiconductor devices to be tested. When all the semiconductor devices to be tested have been tested, the test is ended (Step S210), and the testing process C is ended (Step S211).

Next, an example of another semiconductor testing method using semiconductor testing equipment 98 will be described.

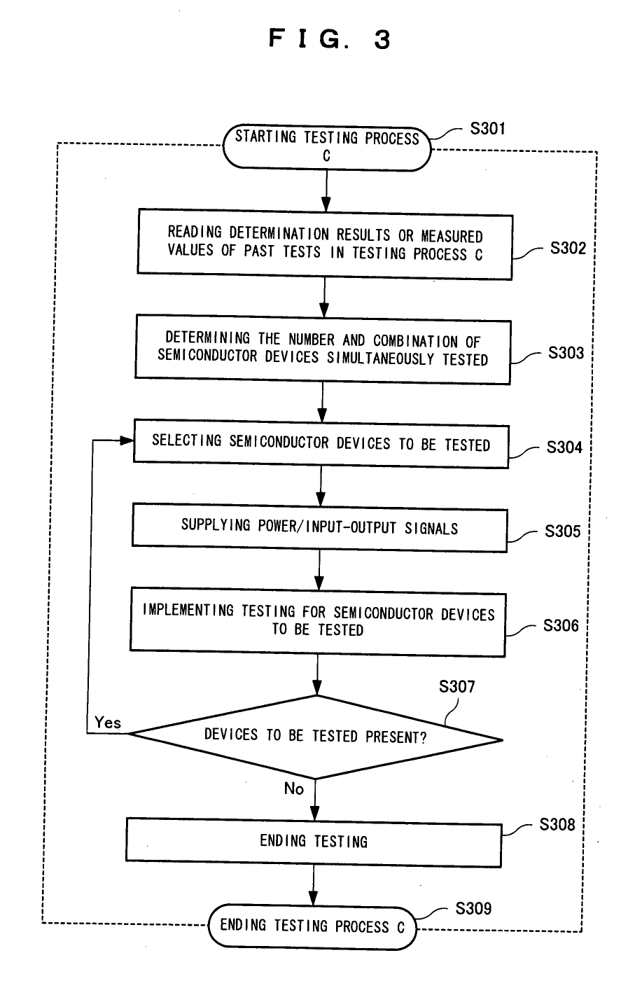

FIG. 3 is a flow diagram showing the flow of another semiconductor testing method for the semiconductor testing equipment according to the first embodiment. The first embodiment will be described referring to a semiconductor device A 106, a semiconductor device B 107, and a semiconductor device C 108 in the semiconductor testing equipment 98 shown in FIG. 1 as examples.

In the testing process C, the test of the wafer 101 using the semiconductor testing equipment 98 is started (Step S301).

First, required parameters for another wafer carrying semiconductor devices equivalent to the semiconductor devices mounted on the wafer 101, used in the testing process C are loaded in the memory 99 from the database wherein past results of testing in the testing process C are accumulated (Step S302). Normally, a semiconductor device produces a large number of wafers depending on the number of production. The determination results at that time and the results of past test of a wafer equivalent to the wafer 101 are stored in the database. In the testing process C, required parameters among them are stored in the memory 99.

Then, on the basis of the determination results or measured values of past testing in the same test processes stored in the memory 99, the combination determining unit 105 determines the combination of semiconductor devices to be simultaneously tested from the wafer 101. For example, the determination results or measured values include the power current value of a semiconductor device and the result of the yield of each test item for the number of semiconductor devices simultaneously tested. The results are compared with the previously established standard values of each determination result, and the number of semiconductor devices to be simultaneously tested in the testing item C is determined (Step S303).

Then, the semiconductor device A 106, the semiconductor device B 107, and the semiconductor device C 108, which are to be tested are selected from the power-source unit 103 and the input-output signal unit 104 of the semiconductor testing equipment 98 (Step S304) and voltage and current are supplied to the power-source terminals and input terminals of these semiconductor devices in the same timing (Step S305).

Then, these semiconductor devices are operated and simultaneously tested (Step S306). After testing, the presence of semiconductor devices not yet tested is checked (Step S307), and testing is repeated for all the semiconductor devices to be tested. When all the semiconductor devices to be tested have been tested, the test is ended (Step S308), and the testing process C is ended (Step S309).

As described above, in the shipment test of semiconductor devices, on the basis of the determination results or measured values in the previous manufacturing process and in the other testing process, or the determination results or measured values of past testing in the same test processes, the combination of semiconductor devices to be simultaneously tested is determined using the combination determining unit 105 equipped in the configuration of the present invention. By supplying the power-source unit 103 and the input-output signal unit 104 only to the selected semiconductor devices so as not to operate semiconductor devices not to be tested, the semiconductor devices can be tested under more stable testing conditions.

### Second Embodiment

Semiconductor testing equipment and semiconductor testing method according to the second embodiment of the present invention will be described.

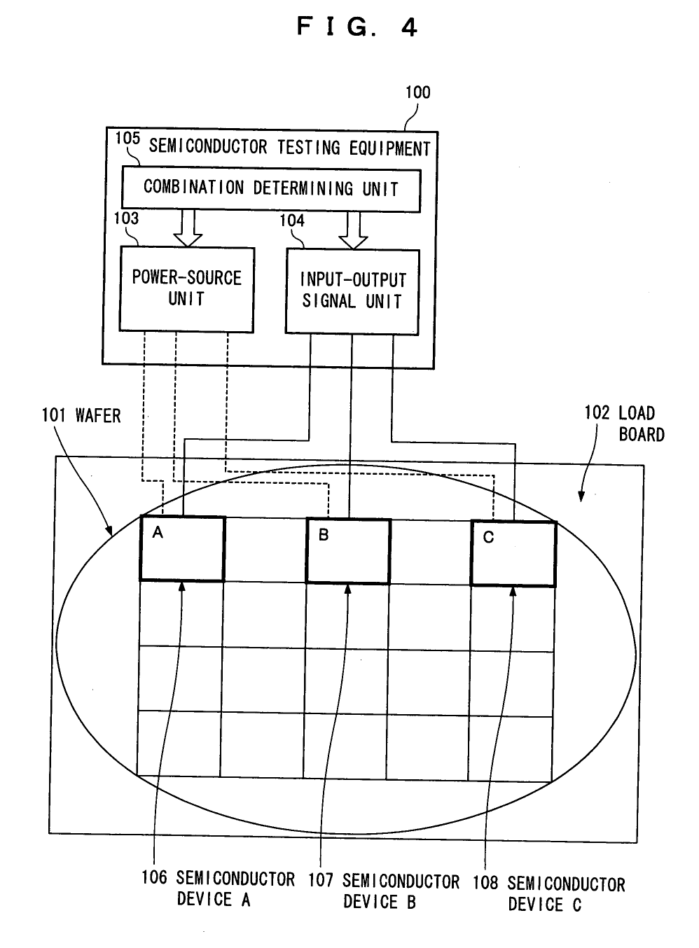

FIG. 4 is a block diagram showing a configuration of semiconductor testing equipment according to the second embodiment of the present invention, and shows the configuration of simultaneous testing of semiconductor devices using the semiconductor testing equipment 100. The test is constituted of the semiconductor testing equipment 100, a wafer 101, and a load board 102 to become the interface for connection between the semiconductor testing equipment 100 and semiconductor devices on the wafer 101. In place of the semiconductor devices on the wafer 101, a semiconductor device assembly sealed in a package may also be used.

The semiconductor testing equipment 100 is equipped with a power-source unit 103 for supplying voltage and current to the power terminals and input-output terminals of semiconductor devices, and input-output signal unit 104. The power-source unit 103 and the input-output signal unit 104 have a plurality of independent power-source circuits, input-output signal circuits, and ports, to supply voltage and current to each of a plurality of semiconductor devices.

When the number of the power-source units 103 and the input-output signal units 104 is smaller than the number of semiconductor devices to be simultaneously tested, the configuration wherein a power-source unit 103 and an input-output signal unit 104 are collectively connected to an arbitrarily determined number of the power terminals and input-output terminals of semiconductor devices, to supply voltage and current may also be used.

In FIG. 4, although the power-source unit 103 and the input-output signal unit 104 are connected only to a semiconductor device A 106, a semiconductor device B 107, and a semiconductor device C 108 among all semiconductor devices mounted on the wafer 101, for the convenience of explanation, actually, they are connected to a number of simultaneously tested semiconductor devices.

The semiconductor testing equipment 100 is further equipped with combination determining unit 105, which is a feature of the present invention. The combination determining unit 105 has a function to determine the combination of semiconductor devices to be simultaneously tested among semiconductor devices to be tested in the second and later tests on the basis of the determination results or measured values of the first test of the semiconductor devices and the performance of the semiconductor testing equipment. The combination determining unit 105 is one of software and hardware wherein previously programmed control algorithm is incorporated. For example, there is a case wherein signal noise caused by output signals of semiconductor devices, or current consumption or voltage variation of the power source of a semiconductor device affects another semiconductor device as a noise via one of the wafer 101 and the load board 102.

Considering such a phenomenon, the combination determining unit 105 determines the number and combination of semiconductor devices to be simultaneously tested in retesting on the basis of measured values observed for each testing item of the test to measure minute noises measured in the first semiconductor device test, the test sensitive to the fluctuation of power voltages, or the test consuming much power current.

For example, when all of the semiconductor device A 106, the semiconductor device B 107, and the semiconductor device C 108 have been determined as defective in the item to test minute output amplitude, and when the semiconductor device A 106 has showed an abnormal power current value or abnormal clock output, there is possibility that the semiconductor device A 106 affects the test for the semiconductor device B 107 and the semiconductor device C 108, and even if retest is conducted, there is possibility that they are determined as defective in the same manner as in the first test.

Therefore, when the second and later tests are conducted, it is determined to conduct the retest for the combination of the semiconductor device B 107 and the semiconductor device C 108 excluding the semiconductor device A 106, and the retest is conducted.

By previously incorporating such an algorithm in the combination determining unit 105, the combination of semiconductor devices to be simultaneously tested among semiconductor devices to be tested in the second and later tests can be determined. When a plurality of semiconductor devices selected using the combination determining unit 105 are tested, only the power-source units 103 and input-output signal units 104 connected to the semiconductor devices to be simultaneously tested are operated, and the power-source units 103 and input-output signal units 104 connected to the semiconductor devices not to be tested are not operated.

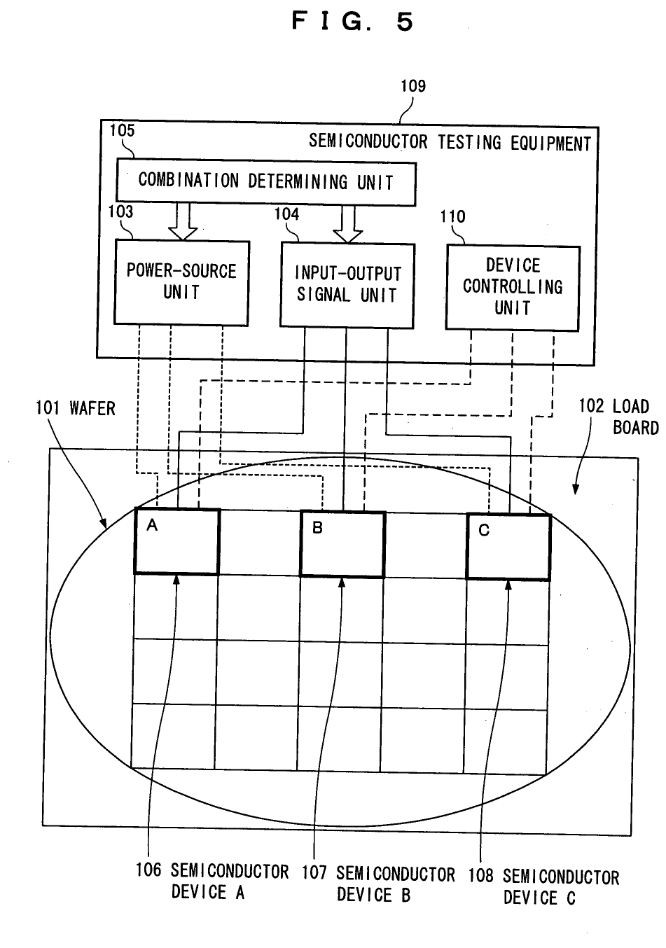

FIG. 5 is a block diagram showing another configuration of semiconductor testing equipment according to the second embodiment, and shows the configuration of simultaneous testing of semiconductor devices using the semiconductor testing equipment 109. The semiconductor testing equipment 109 is different from the semiconductor testing equipment 100 in that the semiconductor testing equipment 109 is equipped with device controlling unit 110, which is another feature of the present invention.

The device controlling unit 110 has a function to output device control signals for controlling the operation of semiconductor devices in accordance with the control algorithm previously established by a program. The device controlling unit 110 may be constituted by a dedicated circuit, or may be constituted by a circuit equivalent to the input-output signal unit 104.

The device controlling unit 110 supplies device control signals for controlling semiconductor devices determined as non-defective in the first semiconductor device test, and controls the devices so as not to generate noise sources that may affect other semiconductor devices, such as the consumption and fluctuation of power current, and the failure to drive output signals, for example, in the resting state of the operation of the semiconductor devices. The control signals outputted from the device controlling unit 110 may be addresses and data for operating a semiconductor device, and may be test signals from the test circuit equipped in the internal circuit of the semiconductor device. The number of lines connected to each semiconductor device can be arbitrarily selected.

The device controlling unit 110 may also have a configuration disposed on the load board 102, other than installing in the semiconductor testing equipment 109. In this case, the information for the test results of each semiconductor device (the coordinate of a device determined as non-defective or defective, the measured values of a semiconductor device determined as defective, and the like) is inputted from the semiconductor testing equipment 109 to the device controlling unit 110.

Although combination determining unit 105 is shown in FIG. 5, the configuration is not necessarily required to have this function.

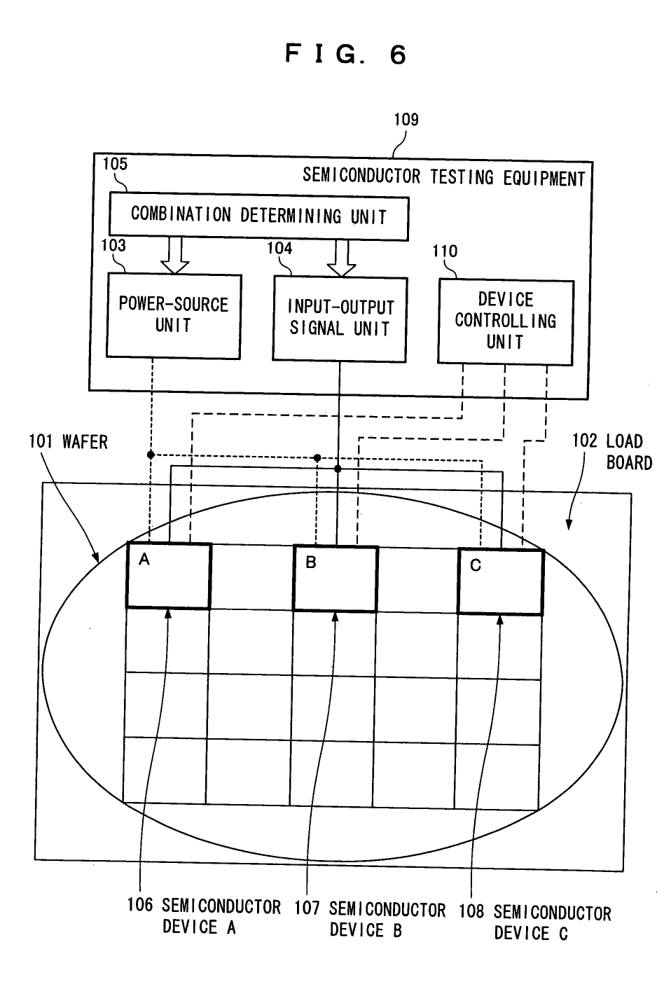

FIG. 6 is a block diagram showing further another configuration of semiconductor testing equipment according to the second embodiment. A power-source unit 103 and an input-output signal unit 104 are collectively connected to the power-source terminals and the input-output terminals of a plurality of semiconductor devices. Particularly in testing semiconductor devices on the wafer 101, there is the case wherein a larger number of, for example, at least 100 semiconductor devices are simultaneously tested.

In this case, since the number of the power-source unit 103 and the input-output signal unit 104 is smaller than the number of semiconductor devices simultaneously tested, a power-source unit 103 and an input-output signal unit 104 are collectively connected to the power-source terminals and the input-output terminals of a number of semiconductor devices that has been arbitrarily selected, and voltage and current are supplied. For the other device controlling unit 110, independent control signal lines for individual semiconductor devices are connected to all the semiconductor devices on the wafer 101 or a number of semiconductor devices simultaneously tested.

Thereby, individual semiconductor devices can be arbitrarily controlled.

The factor to decide control signals from the combination determining unit 105 and the device controlling unit 110 in the above-described semiconductor testing equipment 100 and semiconductor testing equipment 109 may be decided only by the characteristics of a semiconductor device obtained from the measured values among parameters, such as the determination results or measured values of the first semiconductor device test, and the performance of the semiconductor testing equipment.

In configurations of the second embodiment shown in FIGS. 5 and 6, instead of using parameters, such as the determination results or measured values of the first semiconductor device test, and the performance of the semiconductor testing equipment, the configuration for determining the combination of semiconductor devices to be simultaneously tested by the combination determining unit 105 on the basis of the test results in the previous process or past test results in the same test processes as shown in FIG. 1 may be adopted.

In this configuration, the supply of voltage and current to each semiconductor device is performed from one of semiconductor testing equipment 98 and semiconductor testing equipment 109.

Next, a semiconductor testing method using one of semiconductor testing equipment 100 and semiconductor testing equipment 109 will be described.

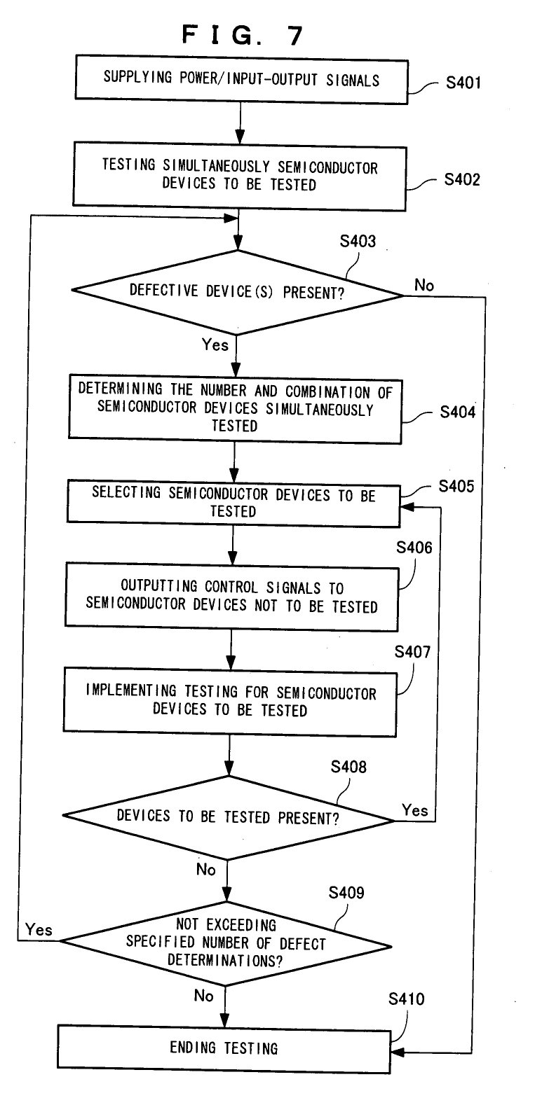

FIG. 7 is a flow diagram showing the flow of a semiconductor testing method for the semiconductor testing equipment according to the second embodiment. In description for the second embodiment, the semiconductor device A 106, the semiconductor device B 107, and the semiconductor device C 108 in the semiconductor testing equipment 109 shown in FIG. 5 or 6 are used as examples.

First, voltage and current are supplied from the power-source unit 103 and the input-output signal unit 104 of the semiconductor testing equipment 109 to the power-source terminals and input terminals of the semiconductor device A 106, the semiconductor device B 107, and the semiconductor device C 108, which are to be tested, in the same timing (Step S401). Then, these semiconductor devices are operated and simultaneously tested (Step S402).

The determination results are monitored from the output terminal of the semiconductor devices, and each semiconductor device is determined to be non-defective or defective (Step S403). As the result of determination, when there is no semiconductor device determined as defective, the test of semiconductor devices to be tested is terminated (Step S410). When there are semiconductor devices determined as defective, the following processes are carried out (Step S404 to Step S409).

In the test using the semiconductor testing equipment 100, the combination of semiconductor devices simultaneously tested in the second test is determined on the basis of the determination results or measured values in the first test, or the properties of the power-source unit 103 and the input-output signal unit 104, such as current capacity and accuracy (Step S404).

For example, all of the semiconductor device A 106, the semiconductor device B 107, and the semiconductor device C 108 have been determined as defective in the item to test minute output amplitude, if the semiconductor device A 106 exhibits an abnormal power current value or an abnormal clock output, the combination determining unit 105 judges that there is possibility that the semiconductor device A 106 affects the test for the semiconductor device B 107 and the semiconductor device C 108 on the basis of measured values of the semiconductor device A 106, and determines the combination to simultaneously test the semiconductor device B 107 and the semiconductor device C 108, excluding the semiconductor device A 106.

After determining the combination, semiconductor devices determined as non-defective and defective are selected (Step S405), and voltage and current are supplied again to the power-source terminals and the input-output terminals from the power-source unit 103 and the input-output signal unit 104, the operation of non-defective devices is controlled by the device controlling unit 110, and for example, the property values of devices such as the power current and output signal driving of the semiconductor devices are set to be minimum, or the mode to make the internal operation to a resting state is set. Alternatively, when the semiconductor devices to be tested and the semiconductor devices not to be tested do not share the power-source unit 103 and the input-output signal unit 104, based on the combination determining unit 105 a method wherein no voltage and current are supplied to the semiconductor devices not to be tested may also be adopted (Step S406).

By such setting, the noise sources generated by the fluctuation of power current and output signals are minimized. On the other hand, the semiconductor devices determined to be defective are retested without supplying control signals to control the operation from the device controlling unit 110 to determine non-defective or defective (Step S407). At this time, since semiconductor devices already determined as non-defective, and semiconductor devices not to be tested among semiconductor devices determined as defective are in the state wherein the devices are not operated, interference by noises between semiconductor devices in retesting can be minimized.

The semiconductor devices that have been determined as non-defective are not determined again whether they are non-defective or not. Retesting of the second time and later is repeated only for the predetermined number of times for determining detectives (Step S409), and semiconductor devices that have been determined as defective are retested.

As described above, when semiconductor devices once determined as defective are retested in the shipping test of semiconductor devices, the combination of semiconductor devices to be simultaneously tested among the semiconductor devices to be tested for the second time and later is determined using the combination determining unit 105 equipped in the configuration of the present invention, on the basis of the determination results or measured values of the first test for semiconductor devices, or the performance of the semiconductor testing equipment. By supplying the power-source unit 103 and the input-output signal unit 104 only to a plurality of selected semiconductor devices so as not to make the semiconductor devices not to be tested operate, the semiconductor devices that have been determined as defective can be retested under more stable testing conditions.

Also, by suppressing the operation of the semiconductor devices not to be tested using the device controlling unit 110, and by minimizing the generation of various noises, the semiconductor devices that have been determined as defective can be retested under more stable testing conditions.

Also, when power and signals are collectively supplied to a plurality of semiconductor devices from the power-source unit 103 and/or the input-output signal unit 104, the semiconductor devices become sensitive to interference between the power source and the semiconductor devices, such as the effect of the fluctuation of power voltage due to the consumption of power current, because of the shared sources, i.e. the power-source unit 103 and the input-output signal unit 104, and there is possibility that the semiconductor devices are determined as defective, which would otherwise be determined as non-defective. Even under such conditions, retesting can be conducted without receiving the effect of interference by other devices by the device controlling unit 110 equipped in the configuration of the present invention.

Further, even by the configuration wherein only the properties of semiconductor devices led from the measured values of the first test for semiconductor devices are fed back, second and later tests can be realized under stable conditions using the combination determining unit 105 and the device controlling unit 110 equipped in the semiconductor testing equipment 100 or the semiconductor testing equipment 109.

### Third Embodiment

Semiconductor testing equipment and semiconductor testing method according to the third embodiment of the present invention will be described.

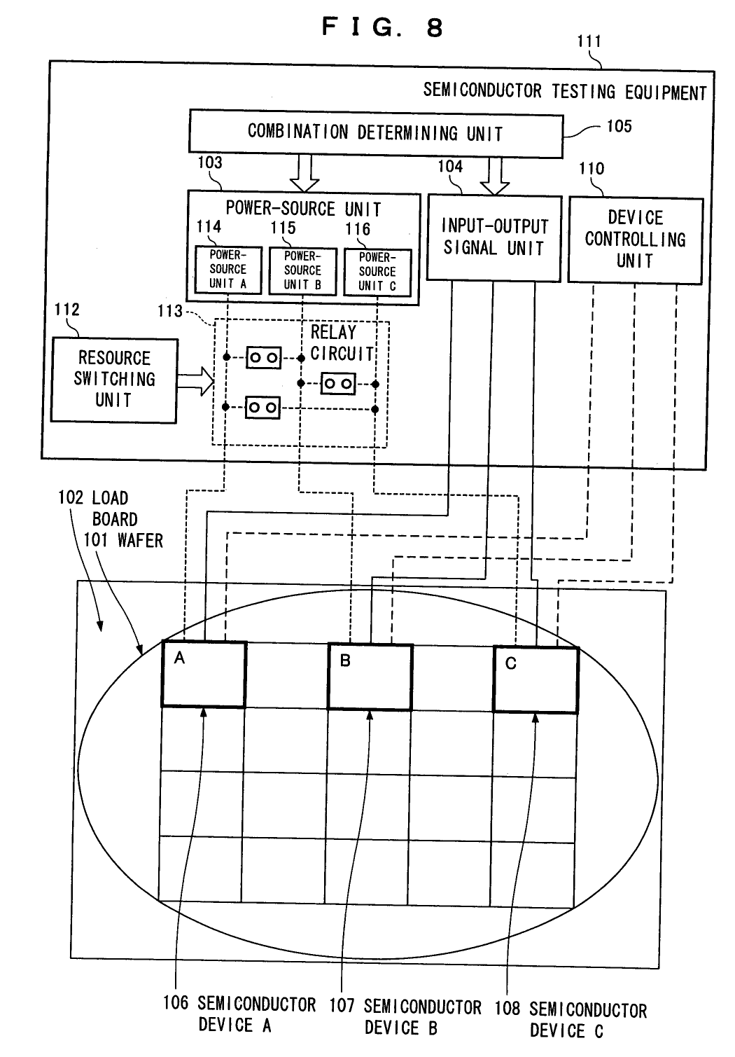

FIG. 8 is a block diagram showing a configuration of semiconductor testing equipment according to the third embodiment, and shows a configuration of simultaneous test of semiconductor devices using semiconductor testing equipment 111. Circuits having the same functions of the circuits as in the second embodiment are denoted by the same reference numerals.

Different from the case of the second embodiment, resource switching unit 112, a relay circuit 113 connected to the power-source lines between the power-source terminals of the power-source unit 103 and semiconductor devices, and parallel power-source lines are newly equipped in the semiconductor testing equipment 111. Although a combination determining unit 105 is shown in FIG. 8, a configuration without this function can also be used.

The resource switching unit 112 has a function to intensely assign to semiconductor devices to be tested, the resources of semiconductor testing equipment, such as a power-source unit, input-output signal unit, and measurement unit, which are used to test the semiconductor devices, on the basis of one of the results and values measured in the semiconductor devices, and the performance of the semiconductor testing equipment 111.

For example, the power-source unit 103 will be described below as an example.

The power-source unit 103 has a plurality of independent power-source circuits and ports, and supplies power to each of a plurality of semiconductor devices. In FIG. 8, the configuration is described using a power-source unit A 114, a power-source unit B 115, and a power-source unit C 116 equipped in the power-source unit 103 for the convenience of description.

The power-source unit A 114, the power-source unit B 115, and the power-source unit C 116 are connected to the power-source terminals of a semiconductor device A 106, a semiconductor device B 107, and a semiconductor device C 108, respectively. Each of the semiconductor device A 106, the semiconductor device B 107, and the semiconductor device C 108 is a semiconductor device to be simultaneously tested. These power-source lines include, for example, parallel relay circuit 113 and parallel power-source lines shown in FIG. 8.

Here, the configuration can connect a plurality of power-source circuits in the power-source unit 103 in parallel, and can supply resources to a semiconductor device by switching connection in the relay circuit 113 using the resource switching unit 112. Voltage and current are supplied to each semiconductor device from the semiconductor testing equipment 111.

Next, a semiconductor testing method according to the third embodiment will be described.

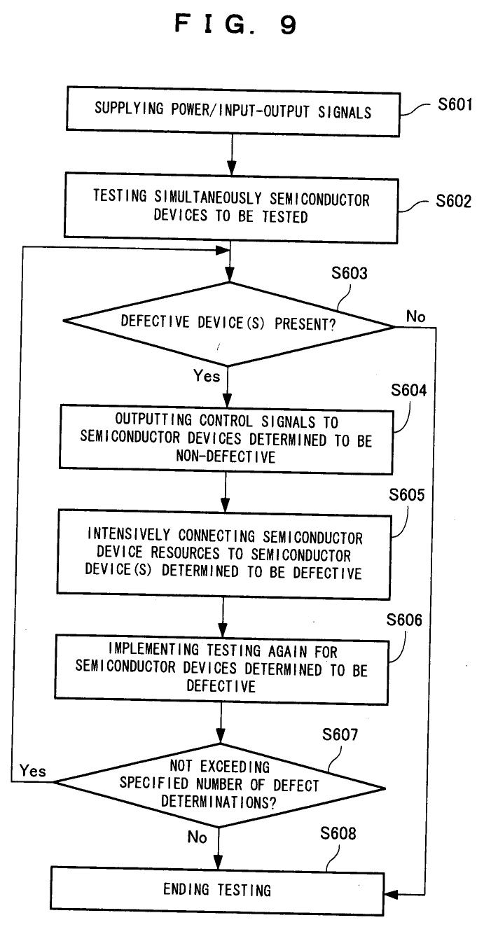

FIG. 9 is a flow diagram showing the flow of a semiconductor testing method for the semiconductor testing equipment according to the third embodiment. Different from the second embodiment, the resources of semiconductor testing equipment are intensively assigned to the semiconductor devices to be tested using the resource switching unit 112.

First, voltage and current are supplied from the power-source unit A 114, the power-source unit B 115, and the power-source unit C 116 in the power-source unit 103 and the input-output signal unit 104 of the semiconductor testing equipment 111 to the power-source terminals and input terminals of the semiconductor device A 106, the semiconductor device B 107, and the semiconductor device C 108, which are to be tested, in the same timing (Step S601).

Then, these semiconductor devices are operated and simultaneously tested (Step S602). The test results are monitored from the output terminals of semiconductor devices, and each semiconductor device is determined as non-defective or defective (Step S603). When there is no semiconductor device determined as defective in the result of determination, the test of the semiconductor devices to be tested is terminated (Step S608). When there are semiconductor devices determined as defective, next processes (Step S604 to Step S607) are carried out.

The case wherein, for example, a semiconductor device A 106 was determined as defective, and a semiconductor device B 107 and a semiconductor device C 108 were determined as non-defective will be described.

First, from the result of measured values of the semiconductor device A 106 determined as defective, it is assumed to be determined as defective, for example, in the item related to current supplying capacity. In this case, by the resource switching unit, the relay circuit 113 of the power-source line is controlled, and the power-source unit A 114 and the power-source unit B 115 are connected in parallel. The power-source unit C 116 can also be controlled to connect in parallel (Step S605).

Next, voltage and current are supplied again to the power-source terminal and the input-output terminal of each of semiconductor devices determined as non-defective and defective from the power-source unit 103 and the input-output signal unit 104. At the same time, control signals for controlling the operation of devices to the semiconductor device B 107 and the semiconductor device C 108 determined as non-defective from the device controlling unit 110 are outputted (Step S606).

By the control signals, control for minimizing the characteristic values of the devices, such as the power current and output signal driving of the semiconductor devices is performed. For example, the mode to make the internal operation of semiconductor devices in a resting state is set. By such setting, the noise sources generated by the fluctuation of power current or output signals are minimized. On the other hand, the semiconductor device A 106 determined to be defective is retested without supplying control signals to control the operation from the device controlling unit 110 to determine non-defective or defective.

At this time, since the semiconductor device B 107 and the semiconductor device C 108 already determined as non-defective are in the resting state, the power-source unit A 114 and the power-source unit B 115 connected in parallel supply power substantially to the semiconductor device A 106. By supplying power from a plurality of power-source units, retesting can be conducted under the state wherein current capacity has been improved.

The determination to be non-defective or defective is not conducted again for the semiconductor device B 107 and the semiconductor device C 108 that have been determined as non-defective. This process is repeated for a predetermined number of times (Step S607) to retest semiconductor devices determined as defective.

As described above, in the shipping test of semiconductor devices, when semiconductor devices once determined as defective are to be retested, by intensively assigning resources, such as the power-source unit, the input-output signal unit, and the measuring unit which are used to test the semiconductor devices, and utilizing the performance of each unit, the semiconductor devices determined as defective can be retested under more stable testing conditions.

### Fourth Embodiment

Semiconductor testing equipment and semiconductor testing method according to the fourth embodiment of the present invention will be described. Here, as the fourth embodiment, an embodiment using either one of semiconductor testing equipment 100, semiconductor testing equipment 109, and semiconductor testing equipment 111 will be described. Here, the method will be described using semiconductor testing equipment 100 as an example.

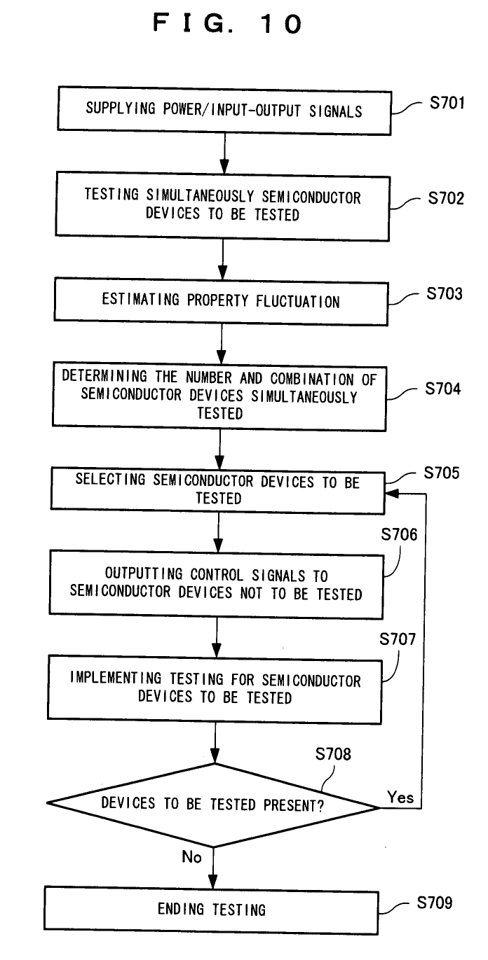

FIG. 10 is a flow diagram showing the flow of a semiconductor testing method for the semiconductor testing equipment according to the fourth embodiment of the present invention. In the description for the fourth embodiment, a semiconductor device A 106, a semiconductor device B 107, and a semiconductor device C 108 shown in FIG. 4 are used as examples.

First, using the power-source unit 103 and the input-output signal unit 104 of the semiconductor testing equipment 100 (Step S701), the properties of arbitrarily selected semiconductor devices are measured (Step S702). For example, the properties of the semiconductor device A 106 are measured. The number of semiconductor devices whose properties are measured can be arbitrarily selected.

Next, the variation of characteristic values when a plurality of semiconductor devices are simultaneously measured is estimated in accordance with previously programmed algorithm on the basis of the measured characteristic values (Step S703). For example, increase and decrease in the consumption of power current and the amplitude of output signals when a plurality of semiconductor devices are simultaneously measured are estimated on the basis of the consumption of power current in the power-source terminal and the amplitude of signals in the output terminal.

On the basis of the result of estimation, considering the test items and the performance of each unit in the semiconductor testing equipment 100, the optimal number and combination of semiconductor devices to be simultaneously tested are determined (Step S704). For the determination of combination, combination determining unit 105 shown in FIG. 4 may also be used.

As a result, the semiconductor device A 106 and the semiconductor device B 107 are selected (Step S705), and after selecting, voltage and current are supplied to the semiconductor device A 106 and the semiconductor device B 107 (Step S706). At this time, although voltage and current are also supplied to the semiconductor device C 108, control signals for controlling the operation of semiconductor devices using the device controlling unit 110 are outputted to the semiconductor device C 108 (Step S706). By the control signals, control for minimizing the characteristic values of the devices, such as the power current and output signal driving of the semiconductor devices is performed. For example, the mode to make the internal operation of semiconductor devices in a resting state is set.

After minimizing the power fluctuation of semiconductor devices not to be tested and the interference of signals using such setting, the semiconductor devices to be tested are tested (Step S707).

As described above, in the shipping test of semiconductor devices, and testing methods using any of these configurations, by estimating the variation of properties on the basis of previously measured characteristic values of semiconductor devices, determining the number and combination of semiconductor devices to be simultaneously tested, and outputting control signals to semiconductor devices not to be tested to make the operation in a resting state, semiconductor devices to be tested can be tested under more stable testing conditions.

What is claimed is:

1. Semiconductor testing equipment for simultaneously testing electric properties of a plurality of semiconductor devices, comprising combination determining unit for determining a combination of simultaneous testing for the semiconductor devices to be tested by the semiconductor testing equipment, on the basis of one of test results or measured values in testing or manufacturing in a separate process implemented before the test conducted using the semiconductor testing equipment, and past determination results or measured values in the same test processes using the semiconductor testing equipment.

2. Semiconductor testing equipment for simultaneously testing electric properties of a plurality of semiconductor devices, comprising combination determining unit for determining a combination of simultaneous testing for the semiconductor devices to be tested in the second test and later, on the basis of one of the determination results and measured values in the first testing for the plurality of semiconductor devices, and the performance of the semiconductor testing equipment.

3. Semiconductor testing equipment for simultaneously testing electric properties of a plurality of semiconductor devices, comprising device controlling unit wherein device controlling signals for controlling the state of the operation of semiconductor devices not to be tested are programmably generated and supplied in testing, on the basis of one of the determination results and measured values in the first testing for the plurality of semiconductor devices, and one of the combination of simultaneous testing for the semiconductor devices and the performance of the semiconductor testing equipment.

4. The semiconductor testing equipment according to claim 3, further comprising a power-source unit for devices that supplies a voltage and current to the plurality of semiconductor devices in common, and an input-output signal unit that transfers electric signals between the plurality of semiconductor devices in common.

5. The semiconductor testing equipment according to claim 4, wherein the combination determining unit determines the combination of simultaneous testing for the semiconductor devices, on the basis of property values in the tests of the power-source unit for devices and the input-output signal unit, and the device controlling unit generates signals for controlling the state of the operation of semiconductor devices not to be tested as the device controlling signals.

6. The semiconductor testing equipment according to claim 1, further comprising resource switching unit for intensively assigning to semiconductor devices to be tested, resources including the power-source unit, the input-output signal unit, and a measuring unit used for testing the semiconductor devices, on the basis of one of the determination results and the measured values, and one of the combination and the performance.

7. The semiconductor testing equipment according to claim 2, further comprising resource switching unit for intensively assigning to semiconductor devices to be tested, resources including the power-source unit, the input-output signal unit, and the measuring unit used for testing the semiconductor devices, on the basis of one of the determination results and the measured values, and one of the combination and the performance.

8. The semiconductor testing equipment according to claim 3, further comprising resource switching unit for intensively assigning to semiconductor devices to be tested, resources including the power-source unit, the input-output signal unit, and the measuring unit used for testing the semiconductor devices, on the basis of one of the determination results and the measured values, and one of the combination and the performance.

9. A semiconductor testing method using semiconductor testing equipment according to claim 1, comprising: a process for reading one of determination results or measured values in testing or manufacturing in a separate process implemented before the test conducted using the semiconductor testing equipment, and past determination results or measured values in the same test processes using the semiconductor testing equipment; a process for determining the combination of semiconductor devices to be simultaneously tested in the semiconductor devices, on the basis of one of the determination results and the measured values; and a process for simultaneously testing the electrical properties of the semiconductor devices to be simultaneously tested according to the combination.

10. A semiconductor testing method using semiconductor testing equipment according to claim 3, comprising: a process for simultaneously testing the electrical properties of the plurality of semiconductor devices; a process for determining the combination of semiconductor devices to be simultaneously tested among the semiconductor devices determined as defective, on the basis of the determination results or measured values in the test of the plurality of semiconductor devices and the performance of the semiconductor testing equipment; a process for outputting device controlling signals to control the state of the operation of semiconductor devices determined as non-defective; and a process for retesting the electrical properties of semiconductor devices determined as defective.

11. A semiconductor testing method using semiconductor testing equipment according to claim 4, comprising: a process for simultaneously testing the electrical properties of the plurality of semiconductor devices; a process for determining the combination of semiconductor devices to be simultaneously tested among the semiconductor devices determined as defective, on the basis of the determination results or measured values in the test of the plurality of semiconductor devices and the performance of the semiconductor testing equipment; a process for outputting device controlling signals to control the state of the operation of semiconductor devices determined as non-defective; and a process for retesting the electrical properties of semiconductor devices determined as defective.

12. A semiconductor testing method using semiconductor testing equipment according to claim 5, comprising: a process for simultaneously testing the electrical properties of the plurality of semiconductor devices; a process for determining the combination of semiconductor devices to be simultaneously tested among the semiconductor devices determined as defective, on the basis of the determination results or measured values in the test of the plurality of semiconductor devices and the performance of the semiconductor testing equipment; a process for outputting device controlling signals to control the state of the operation of semiconductor devices determined as non-defective; and a process for retesting the electrical properties of semiconductor devices determined as defective.

13. A semiconductor testing method using semiconductor testing equipment according to claim 6, comprising: a process for simultaneously testing the electrical properties of the plurality of semiconductor devices; a process for intensively assigning to semiconductor devices to be tested, resources including the power-source unit, the input-output signal unit, and the measuring unit used for testing the semiconductor devices determined as defective; and a process for retesting the electrical properties of semiconductor devices determined as defective.

14. A semiconductor testing method using semiconductor testing equipment according to claim 2, comprising: a process for measuring the electrical properties of arbitrarily selected semiconductor devices among the plurality of semiconductor devices; a process for estimating property fluctuation on the basis of the property values and determining semiconductor devices to be simultaneously tested; a process for outputting signals to control the state of the operation of semiconductor devices not to be tested as the device controlling signals; and a process for simultaneously testing electrical properties of semiconductor devices to be tested.

15. A semiconductor testing method using semiconductor testing equipment according to claim 3, comprising: a process for measuring the electrical properties of arbitrarily selected semiconductor devices among the plurality of semiconductor devices; a process for estimating property fluctuation on the basis of the property values and determining semiconductor devices to be simultaneously tested; a process for outputting signals to control the state of the operation of semiconductor devices not to be tested as the device controlling signals; and a process for simultaneously testing electrical properties of semiconductor devices to be tested.

16. A semiconductor testing method using semiconductor testing equipment according to claim 4, comprising: a process for measuring the electrical properties of arbitrarily selected semiconductor devices among the plurality of semiconductor devices; a process for estimating property fluctuation on the basis of the property values and determining semiconductor devices to be simultaneously tested; a process for outputting signals to control the state of the operation of semiconductor devices not to be tested as the device controlling signals; and a process for simultaneously testing electrical properties of semiconductor devices to be tested.

17. A semiconductor testing method using semiconductor testing equipment according to claim 5, comprising: a process for measuring the electrical properties of arbitrarily selected semiconductor devices among the plurality of semiconductor devices; a process for estimating property fluctuation on the basis of the property values and determining semiconductor devices to be simultaneously tested; a process for outputting signals to control the state of the operation of semiconductor devices not to be tested as the device controlling signals; and a process for simultaneously testing electrical properties of semiconductor devices to be tested.

18. A semiconductor testing method using semiconductor testing equipment according to claim 6, comprising: a process for measuring the electrical properties of arbitrarily selected semiconductor devices among the plurality of semiconductor devices; a process for estimating property fluctuation on the basis of the property values and determining semiconductor devices to be simultaneously tested; a process for outputting signals to control the state of the operation of semiconductor devices not to be tested as the device controlling signals; and a process for simultaneously testing electrical properties of semiconductor devices to be tested.
